(19) United States
(12) Patent Application Publication
(10) Pub. No.: US 2010/0018046 A1
(43) Pub. Date: Jan. 28, 2010

(54) Method for the production of an identification carrier or electronic key for electronically actuated locks

(75) Inventor: Reinhard Pöllabauer, Vienna (AT)

Correspondence Address: CHAPMAN AND CUTLER, 111 WEST MONROE STREET, CHICAGO, IL, 60603, US

(73) Assignee: EVVA-WERK SPEZIALERZEUGUNG VON ZYLINDER- UND SICHERHEITSSCHLOSSERN GESELLSCHAFT m.b.H. & Co.,KG, Vienna (AT)

(21) Appl. No.: 12/311,677

(22) PCT Filed: Oct. 10, 2007
(86) PCT No.: PCT/AT2007/000474

§ 371 Date: Apr. 8, 2009

(30) Foreign Application Priority Data
Oct. 11, 2006 (AT) A 1694/2006

(51) Int. Cl. H05K 3/00

(52) U.S. Cl. 29/829

(57) ABSTRACT

In a method for producing an identification carrier or electronic key for electrically actuatable locks, an integrated circuit having at least one memory component is applied on a carrier by a printing process and an identification code is stored in the memory component.

The invention relates to a method for producing an identification carrier or electronic key for electrically actuatable locks.

Identification carriers or electronic keys for actuating electrically actuatable locks have become known in various configurations. Magnetic cards have, for instance, become known, in whose magnetic strips electric codes are stored, which can be read out upon insertion of the magnetic card into a suitable reading device, whereby access authorization is determined as a function of the read-out code and the lock is opened, if appropriate. Furthermore, identification carriers or electronic keys have become known, from which the identification code stored can be read out in a wireless manner. In this context, transponder keys operating on the basis of RFID (radio frequency identification) technology are to be mentioned, in particular.

The structure of an RFID transponder basically comprises an antenna, an analogue receiving and transmitting circuit (transponder) as well as a digital circuit and a permanent memory. RFID communication between a lock and a transponder key functions in the following way: The reading device arranged in the lock or in the vicinity of the lock generates an electromagnetic or magnetic HF field which is received by the antenna of the RFID transponder. An induction current is formed in the antenna coil as soon as the latter approaches the electromagnetic or magnetic field. This induction current activates the microchip in the transponder key. With a passive transponder, the induced current additionally charges a capacitor which ensures permanent power supply to the chip. With active transponder keys, this will be done by an installed battery. Upon activation of the microchip, the transponder key will receive instructions from the reading device, with the identification code stored in the memory usually being transmitted from the key to the lock in response to such instructions.

On the other hand, it is known to provide goods, articles or safety documents with electronically readable information by the aid of RFID transponders. WO 00/07151 A1 describes the application of RFID technology for securing security papers such as, for instance, banknotes, checks, shares and stocks etc. The output signal emitted by the RFID transponder and containing the identification information constitutes an authenticity feature and is verified in order to verify the authenticity of the safety document. The output signal which is emitted by the RFID transponder when coupling in the carrier frequency, for instance, contains the individual serial number of the safety document, which is also imprinted on the safety document. In order to verify these two pieces of information, it is checked whether the safety document is a forgery or not.

EP 1134694 A1 too describes the application of a transponder on a safety document. Also there, the transponder serves as a feature to recognize forgeries or to locate the document.

WO 03/057501 A1 describes a security or safety document onto which an electronic circuit can be attached, wherein at least one element of the electronic circuit is printed on the security or safety document. An electrically conductive ink is used to produce conductors or other electrically conductive structures of the circuit. A suitable electrically conductive ink, for instance, comprises an electrically conductive polymer. Such electrically conductive polymers are known per se from the prior art. Furthermore, insulating and/or dielectric and/or highly permeable and/or piezoelectric inks can be used to realize circuit structures. From organic semiconductor technology, the application of organic semi-conducting layers made, for instance, of conjugated polymers like polythiophenes, polythienylene vinylene or polyfluorene derivatives is known. The layers or inks are preferably applied by a printing process such as, for instance, ink jet printing, screen printing, letterpress printing, intaglio printing and flat printing in already partially structured or patterned states.

The use of printing techniques for applying electronic circuits on security papers or safety documents such as, for instance, banknotes have so far involved the advantage of the electric circuit being adapted to the mechanical flexibility of the security paper or safety document, thus leaving the manipulation of the security paper or safety document unaffected.

The present invention aims to provide a method for producing an identification carrier or electronic key, wherein the key obtained by said method is to be suitable, in particular, for short-term applications, for instance in the context of hotel room locking systems, wherein objects of any kind are to be additionally usable as keys.

To solve this object, the method according to the invention is substantially characterized in that an integrated circuit having at least one memory component is applied on a carrier at least partially by a printing process, and that an identification code is stored in said memory component. By applying the circuit including the identification code on a carrier by a printing process, the use of almost any carrier is possible, said carrier turning into a key by the imprinting of an integrated circuit and subsequent storage of the respective identification code. The function of a key can thus be imparted to any desired object by imprinting the circuit on the same, so that such a key will always be available with an appropriately selected carrier and need not be carried along separately. In the context of hotel room locking systems it is, for instance, conceivable that the hotel guest provides a personal object such as, for instance, their passport or an identification card, on which the integrated circuit is imprinted by a printing process, whereby, after the attachment or storage of the identification code by the imprinting process (e.g. ROM), the passport or identification card has become the hotel key. By appropriately programming the hotel room locking system, it may be provided that the identification code assigned to the respective hotel guest will only be valid during the guest's stay. Upon expiration of the validity, the identification code will consequently be deleted from the list of access authorizations such that the necessity to again remove the integrated circuit from the personal object of the hotel guest will be obviated. The integrated circuit may rather remain on the personal object, wherein the imprinted circuit may optionally be eliminated by the hotel guest themselves by removing the ink using suitable solvents.

According to the invention, the circuit is at least partially applied by a printing process. In doing so, the antenna provided for transmitting and receiving data may, for instance, be applied by conventional methods. Alternatively, the antenna too is applied by a printing process.

In order to extend the durability of the applied circuit on the carrier surface, it is preferably provided that the applied circuit is covered by a protective layer, for instance a foil.

The universal applicability of the identification carriers to be produced by imprinting circuits on them will, in particular, be ensured even if an adhesive foil is used as said carrier, as in correspondence with a preferred configuration. The integrated circuit is thus imprinted on an adhesive foil, which adhesive foil can subsequently be applied on any desired object so as to make it function as a key. If required, the foil can again be detached from the object in a simple manner.

As already pointed out above, almost all objects are suitable as carriers for the method according to the invention, with paper, cardboard or a plastic card being selected as preferred carriers.

The carrier may, in turn, be applied on an object, in which case special conditions of the object will have to be taken into account. The carrier in this case may, for instance, be a plane, rigid platelet which is applied on an uneven object so as to impart the function of a key even to an object which, on account of its unevenness, is possibly difficult to imprint. If necessary, the carrier can be adapted to the unevenness(es) of the object such that the unevenness(es) will be compensated after the application of the carrier. The carrier may also be designed to be applied on an object while keeping a distance relative to the surface of the object, which will be of particular benefit if the communication between the circuit imprinted on the carrier and the lock would be interfered with by metallic surfaces of the object.

The electronic circuit and the identification code stored therein may cooperate with the lock in any manner whatsoever in order to determine the access authorization and for opening or locking the lock, the combination between the electronic key and the lock for the purpose of reading out the identification code being feasible in both a wireless manner and through contacts. In a preferred manner, it is proceeded such that the electronic circuit is applied to form a transponder chip, and an antenna is, furthermore, applied on the carrier by a printing process. In this manner, a so-called RFID chip can be produced so as to enable the reading of the identification code in a simple, wireless manner and the renunciation of a separate energy supply to the key with a passive configuration of the RFID transponder.

To sum up, the invention is thus related to the use of integrated circuits at least partially produced by a printing process as identification carriers or electronic keys for electrically actuatable locks.

1. A method for producing an identification carrier or electronic key including an integrated circuit having at least one memory component for electrically actuatable locks, comprising the steps of:
applying the integrated circuit on a carrier at least partially by a printing process, and
storing an identification code in said memory component, wherein
said carrier is an adhesive foil, and
said adhesive foil is affixed to a further carrier.

2. A method according to claim 1, wherein said further carrier is paper, cardboard, or a plastic card.

3. A method according to claim 1 wherein said integrated circuit is applied to form a transponder chip, and an antenna is applied on the carrier by a printing process.

4. A method according to claim 1, wherein the applied integrated circuit is covered by a protective layer.

5. A method according to claim 1, wherein the identification code is stored in the memory component by a printing process.

6. A method according to claim 1, wherein the identification code is stored in the memory component by electronic means.

7. A process of using an integrated circuit partially produced by a printing process as an identification carrier or electronic key for electrically actuatable locks.

8. A process of using a desired object with an affixed adhesive foil on which an integrated circuit is at least partially applied by a printing process, as an electronic key for electrically actuatable locks.

9. A method according to claim 4, wherein the protective layer is a foil.

10. A method according to claim 2 wherein said integrated circuit is applied to form a transponder chip, and an antenna is applied on the carrier by a printing process.

11. A method according to claim 2, wherein the applied integrated circuit is covered by a protective layer.

12. A method according to claim 3, wherein the applied integrated circuit is covered by a protective layer.

13. A method according to claim 2, wherein the identification code is stored in the memory component by a printing process.

14. A method according to claim 3, wherein the identification code is stored in the memory component by a printing process.

15. A method according to claim 4, wherein the identification code is stored in the memory component by a printing process.

16. A method according to claim 2, wherein the identification code is stored in the memory component by electronic means.

17. A method according to claim 3, wherein the identification code is stored in the memory component by electronic means.

18. A method according to claim 4, wherein the identification code is stored in the memory component by electronic means.

19. A method according to claim 5, wherein the identification code is stored in the memory component by electronic means.

20. A method according to claim 10, wherein
the applied integrated circuit is covered by a protective layer comprised of a foil, and
the identification code is stored in the memory component by a printing process.
